(19) United States
(12) Patent Application Publication
(10) Pub. No.: US 2026/0040925 A1
(43) Pub. Date: Feb. 5, 2026

(54) RIVET STRUCTURE AND METHOD

(71) Applicant: Micron Technology, Inc., Boise, ID (US)

(72) Inventors: Matthew J. King, Boise, ID (US); David H. Wells, Boise, ID (US); Tyler List, Boise, ID (US); Tom J. John, Boise, ID (US); Mojtaba Asadirad, Boise, ID (US)

(21) Appl. No.: 19/282,049

(22) Filed: Jul. 28, 2025

Related U.S. Application Data
(60) Provisional application No. 63/677,143, filed on Jul. 30, 2024.

(51) Int. Cl. H01L 23/532; H01L 21/768; H01L 23/528; H10B 41/27; H10B 43/27

(52) U.S. Cl. CPC H01L 23/53266; H01L 21/76831; H01L 21/76879; H01L 23/5283; H01L 23/5329; H10B 41/27; H10B 43/27

(57) ABSTRACT

Semiconductor devices and methods are disclosed, including memory cells/memory strings, semiconductor devices and systems. Example semiconductor devices and methods include a stack of alternating dielectric layers and conductor layers, and a vertical conductor passing between a top level of the stack and a bottom level of the stack. Lateral connections are included between a location along the vertical conductor and a selected conductor layer from the stack, wherein a direct interface is formed between the vertical conductor and the selected conductor layer.

### PRIORITY APPLICATION

This application claims the benefit of priority to U.S. Provisional Application Ser. No. 63/677,143, filed Jul. 30, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to interconnect structures in memory devices, such as vertical NAND devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates selected portions of a memory device in a stage of manufacture in accordance with some example embodiments.

FIG. 2B illustrates selected portions of a memory device in another stage of manufacture in accordance with some example embodiments.

FIG. 2C illustrates selected portions of a memory device in another stage of manufacture in accordance with some example embodiments.

FIG. 2D illustrates selected portions of a memory device in another stage of manufacture in accordance with some example embodiments.

FIG. 2E illustrates selected portions of a memory device in another stage of manufacture in accordance with some example embodiments.

FIG. 2F illustrates selected portions of a memory device in another stage of manufacture in accordance with some example embodiments.

FIG. 3 illustrates selected portions of a memory device in accordance with some example embodiments.

FIG. 4 illustrates selected portions of a memory device in accordance with some example embodiments.

FIG. 5 illustrates selected portions of a memory device in accordance with some example embodiments.

FIG. 6 illustrates selected portions of a memory device in accordance with some example embodiments.

FIG. 7 illustrates selected portions of a memory device in accordance with some example embodiments.

FIG. 8 illustrates an example method flow diagram in accordance with other example embodiments.

FIG. 9 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

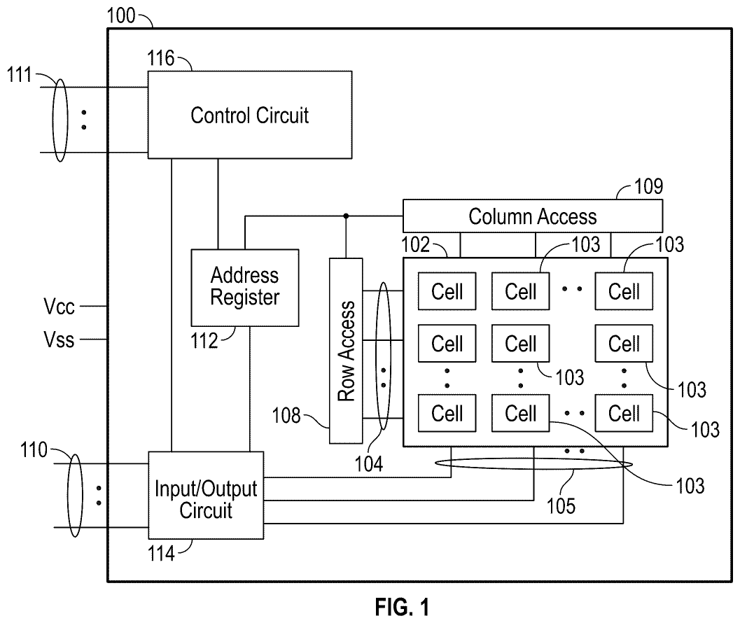

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

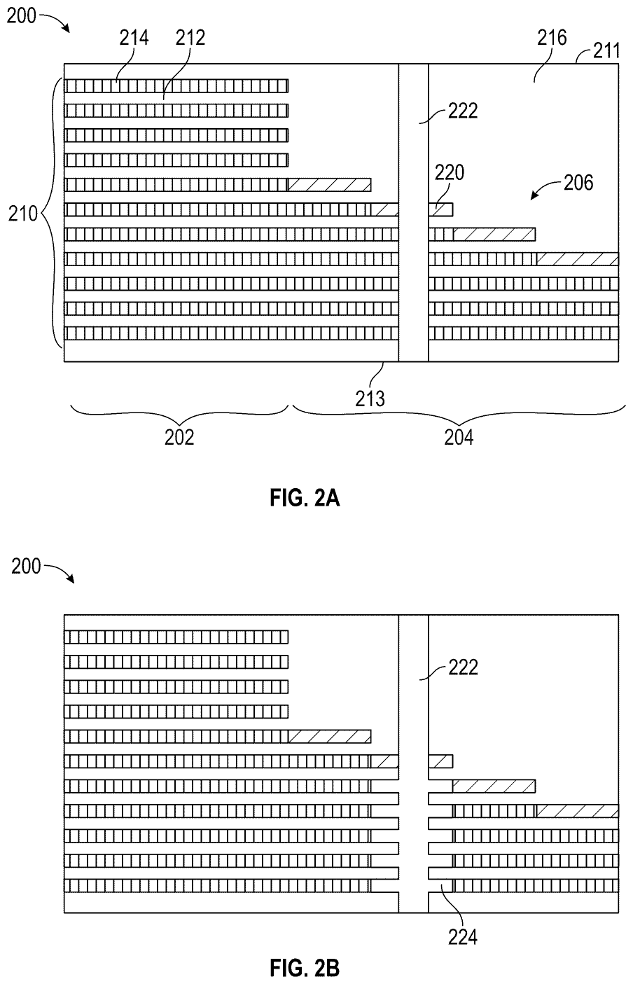

Memory cells 103 and other circuits 114, 116, etc. may include transistors and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2A shows a portion of a memory device 200. The memory device 200 includes a stack 210 of alternating dielectric layers 212 and placeholder layers 214. An array portion 202 of the stack 210 is shown, where memory cells, such as memory strings are formed. An electrical connection portion 204 is shown, adjacent to the array portion 202, where electrical connections are made with selected layers in the stack 210 to form connections with wordlines in an array. FIGS. 2A-2F show selected stages of manufacture to form vertical conductors to connect to selected conductor layers in the stack 210. In one example, the connections form wordline connections.

In FIG. 2A, a staircase 206 is formed in the electrical connection portion 204. One or more etch selective layers 220 are formed on treads of the staircase 206. In one example the etch selective layers 220 are formed by implanting carbon in selected treads of the staircase 206, although the invention is not so limited. In one example, the placeholder layers 214 include nitride, and implanting carbon includes forming carbonitride. In the example of FIG. 2A, an oxide fill 216 is formed over the staircase 206 up to a top surface 211 of the stack 210. In FIG. 2A, a passage 222 is formed between the top surface 211 of the stack 210 and a bottom surface 213 of the stack 210, passing through one of the etch selective layers 220.

In FIG. 2B, one or more lateral cavities 224 are formed, extending from the passage 222. Because the tread or treads of the staircase 206 with etch selective layers 220 are etch selective compared to the oxide fill 216 and the dielectric layers 212 of the stack 210, the lateral cavities only form in the placeholder layers 214 of the stack 210. In one example, the placeholder layers include nitride material, although the invention in not so limited.

In FIG. 2C, a dielectric material 226 is filled into the lateral cavities 224. In one example, the dielectric material 226 includes silicon oxide. In one example, sidewalls of the passage 222 and the lateral cavities 224 are filled with silicon oxide, and then etched. Because the lateral cavities have only a small opening exposed to the passage, they will etch last. In this way, by stopping the etch at a selected time, only the lateral cavities 224 remain with the dielectric material 226 fill.

In FIG. 2D, a second placeholder material 228 is filled into the passage 222. In one example, the second placeholder material 228 includes polysilicon. In FIG. 2D, the placeholder layers 214 of the stack 210 are replaced with conductor layers 230 in a replacement gate process. In one example, nitride material, serving as the placeholder layers 214 is removed through various openings in the stack (not shown) and one or more materials are deposited in their place to form conductor layers 230 separated by dielectric layers 212. In one example, the second placeholder material 228 keeps the passage 222 sealed while the placeholder layers 214 are replaced. In one example, the second placeholder material 228 helps to hold dielectric layers 212 in place until the conductor layers 230 are deposited.

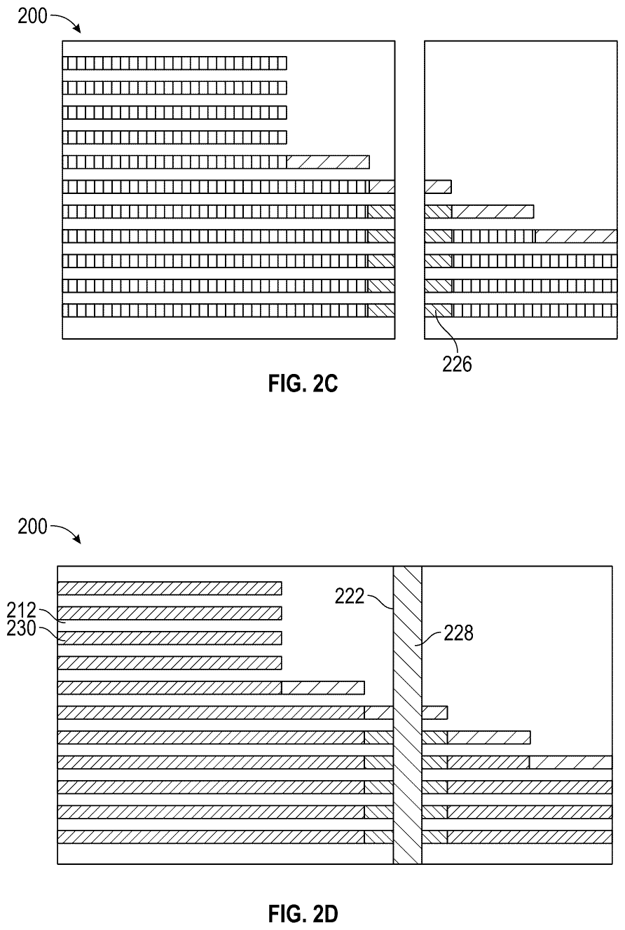

In one example, the conductor layers 230 include a liner interface material that is deposited first, and a core conductor material that fills in the space within the liner interface material. In one example, the liner interface material includes a high-K material such as hafnium oxide, and the core conductor material includes tungsten. In one example, the liner interface material includes a material with a dielectric constant (K) higher than 20, although the invention is not so limited. Conductor layers 230 including high-K materials and tungsten are discussed in more detail in FIGS. 3-7. Core conductor materials other than tungsten are also within the scope of the invention.

In FIG. 2E, after the placeholder layers 214 have been replaced by conductor layers 230, the second placeholder material 228 is removed from the passage 222. The etch selective layer is removed in FIG. 2E by selecting an etchant that preferentially removes the etch selective layer 220, over other materials such as oxide fill 216 and dielectric material 226 fill. A connector lateral cavity 240 is formed where the etch selective layer 220 was removed. In one example, when forming the connector lateral cavity 240, a portion of the liner interface material adjacent to the connector lateral cavity 240 is removed at an end 241 of the connector lateral cavity 240 adjacent to a selected conductor layer 232. This operation is discussed in more detail in FIGS. 3-7.

In FIG. 2F, a vertical conductor 242 is formed. In one example, the vertical conductor 242 includes tungsten. In FIG. 2E, the connector lateral cavity 240 is also filled with a conductor material to form a lateral connection 244 between a location along the vertical conductor 242 and the selected conductor layer 232 from the conductor layers 230 in the stack 210. In one example, the vertical conductor 242 and the lateral connection 244 are integrally formed. Because the portion of the liner interface material adjacent to the connector lateral cavity 240 was removed, the lateral connection 244 forms a direct interface with the core conductor of the selected conductor layer 232. Other conductor layers 230 in the stack 210 still have a liner interface material covering ends of the conductor layers 230.

The vertical conductor 242 and lateral connection 244 shown in FIG. 2F provides an electrical connection between circuit at the top surface 211 of the stack 210 and selected conductor layers 232. The dielectric material 226 provides an electrical isolation between the vertical conductor 242 and other conductor layers 230 that are not the selected conductor layer 232.

FIG. 3 shows a portion of a memory device 300 with a closer view of an interface between an example vertical conductor 342 and an example lateral connection 344 and a selected conductor layer 332. In FIG. 3, a selected conductor layer 332, and other conductor layers 330 are shown. The other conductor layers 330 are electrically isolated from the vertical conductor 342 by dielectric material 326 that forms lateral isolation structures around the vertical conductor 342. In the example shown, the dielectric material 326 forms lateral isolation structures only below a level of the lateral connection 344. Other electrical isolation is provided above the level of the lateral connection 344, such as oxide fill 216 from the example of FIG. 2A.

The selected conductor layer 332 and other conductor layers 330 each include a liner interface material 302 and a core conductor 304. As discussed above, in one example, when the placeholder layers 214 are replaced with conductor material, the conductor material includes the two components of the liner interface material 302 deposited first, and the core conductor 304 filled over the liner interface material 302. In one example, the liner interface material 302 includes a high-K material such as hafnium oxide, and the core conductor material 304 includes tungsten. In one example, the liner interface material includes a material with a dielectric constant (K) higher than 20, although the invention is not so limited. Core conductor materials 304 other than tungsten are also within the scope of the invention.

In the closer detail of FIG. 3, the liner interface material 302 related to the other conductor layers 330 covers a top, bottom, and end 306 of the conductive core 304. However, in the selected conductor layer 332, the liner interface material 302 only covers a top and a bottom of the conductive core 304, and an end 341 of the selected conductor layer 332 forms a direct interface between the conductive core 304 and the lateral connection 344. This configuration results from the process shown in FIGS. 2E and 2F described above. When the connector lateral cavity 240 is formed, any liner interface material 302 at the end 306 of the selected conductor layer 332 is removed, and the conductive core 304 is exposed. Subsequently, when the lateral connection 344 is deposited, it will form a direct interface with the conductive core 304, while the liner interface material 302 still remains on a top and bottom of the selected conductor layer 332. In other conductor layers 330, where the lateral connection 344 is not coupled, the end 306 of the other conductor layers 330 still retains the liner interface material 302.

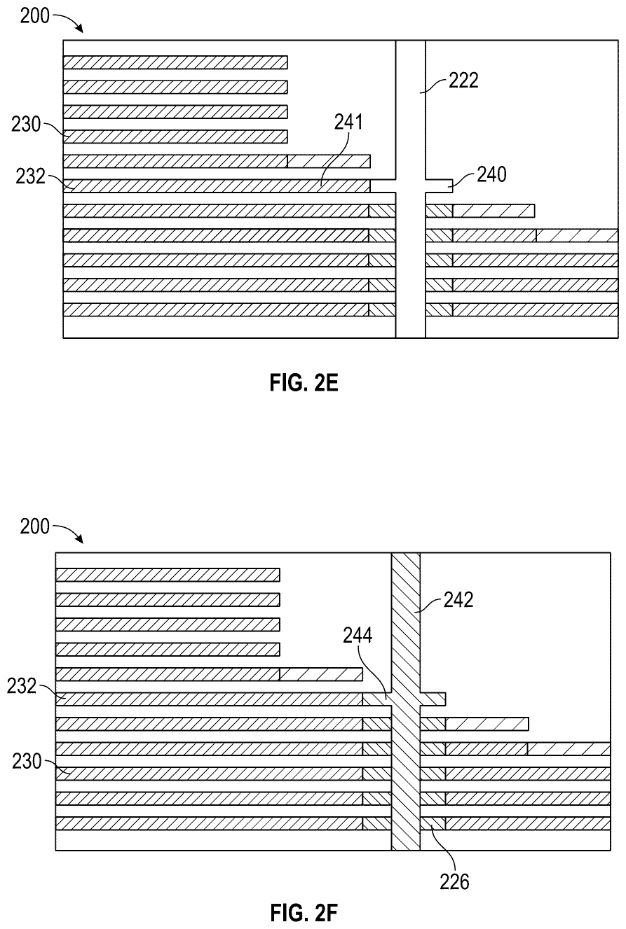

FIG. 4 shows a portion of another example memory device 400 with a closer view of an interface between an example vertical conductor 442 and a selected conductor layer 432. In FIG. 4, a selected conductor layer 432, and other conductor layers 430 are shown. The other conductor layers 430 are electrically isolated from the vertical conductor 442 by dielectric material 426 that forms lateral isolation structures around the vertical conductor 442.

The selected conductor layer 432 and other conductor layers 430 each include a liner interface material 402 and a core conductor 404. Similar to other examples, the liner interface material 402 includes a high-K material such as hafnium oxide, and the core conductor material 304 includes tungsten. In one example, the liner interface material includes a material with a dielectric constant (K) higher than 20, although the invention is not so limited. Core conductor materials 404 other than tungsten are also within the scope of the invention.

In the closer detail of FIG. 4, the liner interface material 402 related to the other conductor layers 430 covers a top, bottom, and end 406 of the conductive core 404. However, in the selected conductor layer 432, the liner interface material 402 only covers a top and a bottom of the conductive core 404, and an end 441 of the selected conductor layer 432 forms a direct interface between the conductive core 304 and the vertical conductor 442.

In the example of FIG. 4, no lateral connection is formed off of the vertical conductor 442. However, when the vertical conductor 442 is formed, any liner interface material 402 at the end of the selected conductor layer 432 is removed, and the conductive core 404 is exposed. Subsequently, when the vertical conductor 442 is deposited, it will form a direct interface with the conductive core 404, while the liner interface material 402 still remains on a top and bottom of the selected conductor layer 432. In other conductor layers 430, where the vertical conductor 442 is not coupled, the end 406 of the other conductor layers 430 still retains the liner interface material 402.

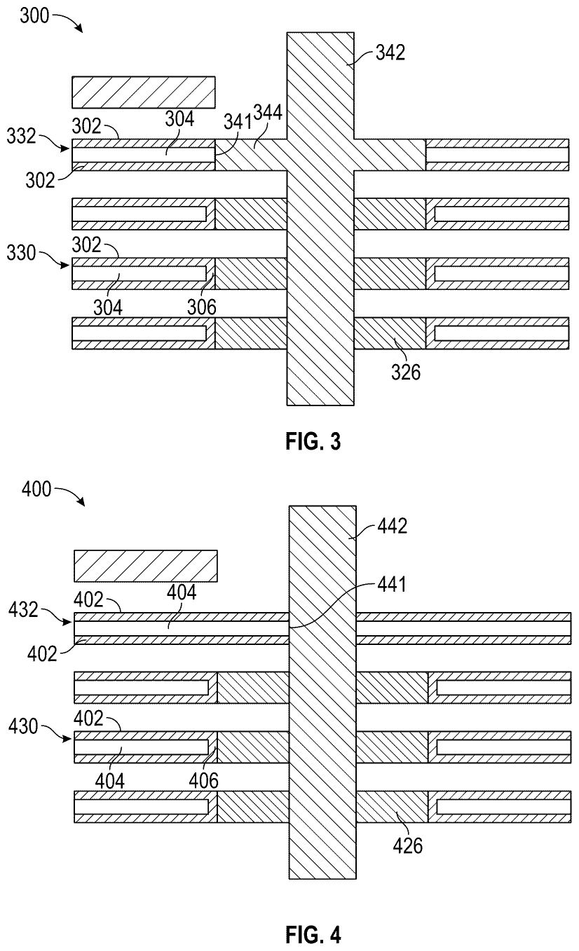

FIG. 5 shows a portion of another example memory device 500 with a closer view of an interface between an example vertical conductor 542 and an example lateral connection 544 and a selected conductor layer 532. In FIG. 5, a selected conductor layer 532, and other conductor layers 530 are shown. The other conductor layers 530 are electrically isolated from the vertical conductor 542 by dielectric material 526 that forms lateral isolation structures around the vertical conductor 542.

The selected conductor layer 532 and other conductor layers 530 each include a liner interface material 502 and a core conductor 504. In one example, the liner interface material 502 includes a high-K material such as hafnium oxide, and the core conductor material 504 includes tungsten. In one example, the liner interface material includes a material with a dielectric constant (K) higher than 20, although the invention is not so limited.

In the closer detail of FIG. 5, the liner interface material 502 related to the other conductor layers 530 covers a top, bottom, and end 506 of the conductive core 504. However, in the selected conductor layer 532, the liner interface material 502 only covers a top and a bottom of the conductive core 504, and an end 541 of the selected conductor layer 532 forms a direct interface between the conductive core 504 and the lateral connection 544.

In the example of FIG. 5, the lateral connection 544 is thicker than the selected conductor layer 532. FIG. 5 shows a first thickness 510 of the lateral connection 544 is thicker than a second thickness 512 of the selected conductor layer 532.

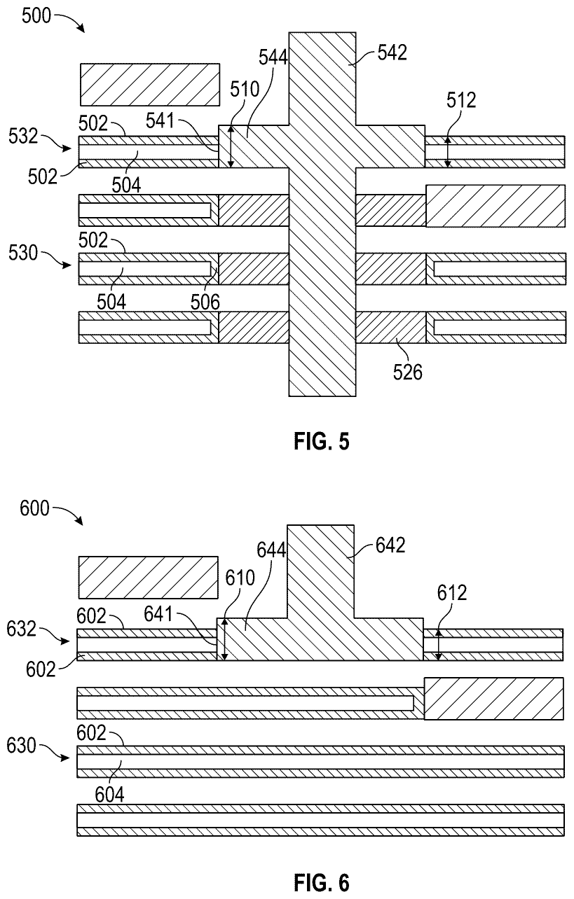

FIG. 6 shows a portion of another example memory device 600 with a closer view of an interface between an example vertical conductor 642 and an example lateral connection 644 and a selected conductor layer 632. In FIG. 6, a selected conductor layer 632, and other conductor layers 630 are shown. In the example of FIG. 6, the vertical conductor 642 does not pass all the way through the stack. In FIG. 6, the vertical conductor 642 stops on a selected tread of the staircase structure, and connects with the selected conductor layer 632 through the lateral connection 644.

The selected conductor layer 632 and other conductor layers 630 each include a liner interface material 602 and a core conductor 604. In one example, the liner interface material 602 includes a high-K material such as hafnium oxide, and the core conductor material 604 includes tungsten. In one example, the liner interface material includes a material with a dielectric constant (K) higher than 20, although the invention is not so limited. In FIG. 6, the liner interface material 602 only covers a top and a bottom of the conductive core 504, and an end 641 of the selected conductor layer 632 forms a direct interface between the conductive core 604 and the lateral connection 644.

In the example of FIG. 6, the lateral connection 644 is thicker than the selected conductor layer 632. FIG. 6 shows a first thickness 610 of the lateral connection 644 is thicker than a second thickness 612 of the selected conductor layer 632.

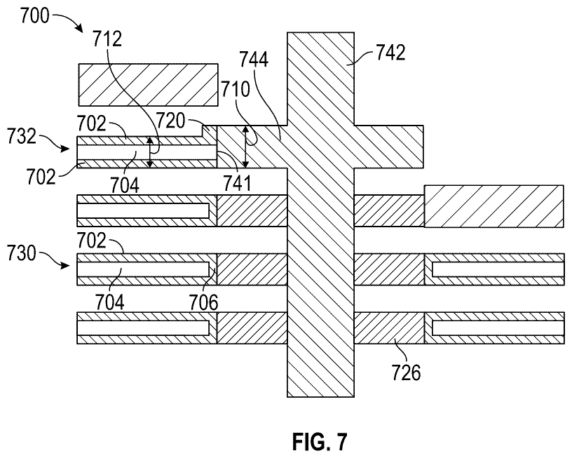

FIG. 7 shows a portion of another example memory device 700 with a closer view of an interface between an example vertical conductor 742 and an example lateral connection 744 and a selected conductor layer 732. In FIG. 7, a selected conductor layer 732, and other conductor layers 730 are shown. The other conductor layers 730 are electrically isolated from the vertical conductor 742 by dielectric material 726 that forms lateral isolation structures around the vertical conductor 742.

The selected conductor layer 732 and other conductor layers 730 each include a liner interface material 702 and a core conductor 704. In one example, the liner interface material 702 includes a high-K material such as hafnium oxide, and the core conductor material 704 includes tungsten. In one example, the liner interface material includes a material with a dielectric constant (K) higher than 20, although the invention is not so limited.

In the closer detail of FIG. 7, the liner interface material 702 related to the other conductor layers 730 covers a top, bottom, and end 706 of the conductive core 704. However, in the selected conductor layer 732, the liner interface material 702 only covers a top and a bottom of the conductive core 704, and an end 741 of the selected conductor layer 732 forms a direct interface between the conductive core 704 and the lateral connection 744.

In the example of FIG. 7, the lateral connection 744 is thicker than the selected conductor layer 732. FIG. 7 shows a first thickness 710 of the lateral connection 744 is thicker than a second thickness 712 of the selected conductor layer 732. Additionally, in the example of FIG. 7, a ledge 720 of liner interface material 702 matches the first thickness 710 of the lateral connection 744.

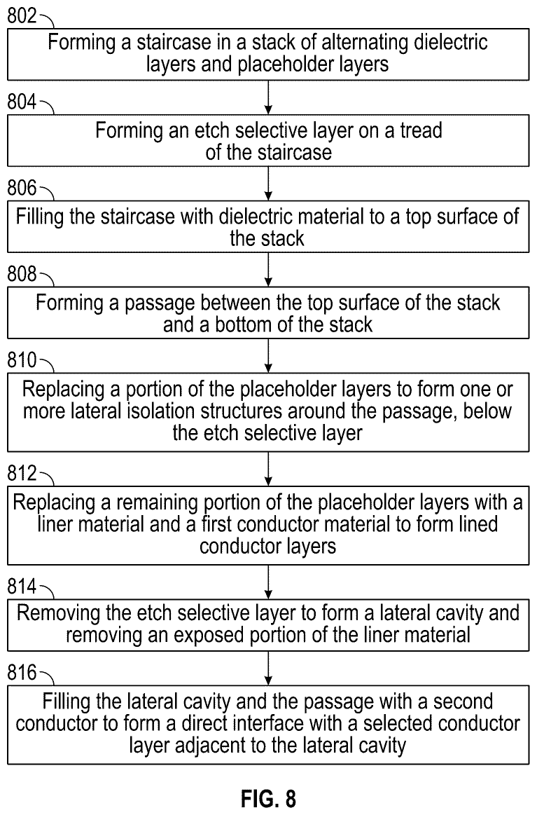

FIG. 8 shows one example of a manufacturing method of forming a memory device as disclosed. In operation 802, a staircase is formed in a stack of alternating dielectric layers and placeholder layers. In operation 804, an etch selective layer is formed on a tread of the staircase. In operation 806, the staircase is filled with dielectric material to a top surface of the stack. In operation 808, a passage is formed between the top surface of the stack and a bottom of the stack.

In operation 810, a portion of the placeholder layers are replaced to form one or more lateral isolation structures around the passage, below the etch selective layer. In operation 812, a remaining portion of the placeholder layers are replaced with a liner material and a first conductor material to form lined conductor layers. In operation 814, the etch selective layer is removed to form a lateral cavity and removing an exposed portion of the liner material, and in operation 816, the lateral cavity and the passage are filled with a second conductor to form a direct interface with a selected conductor layer adjacent to the lateral cavity.

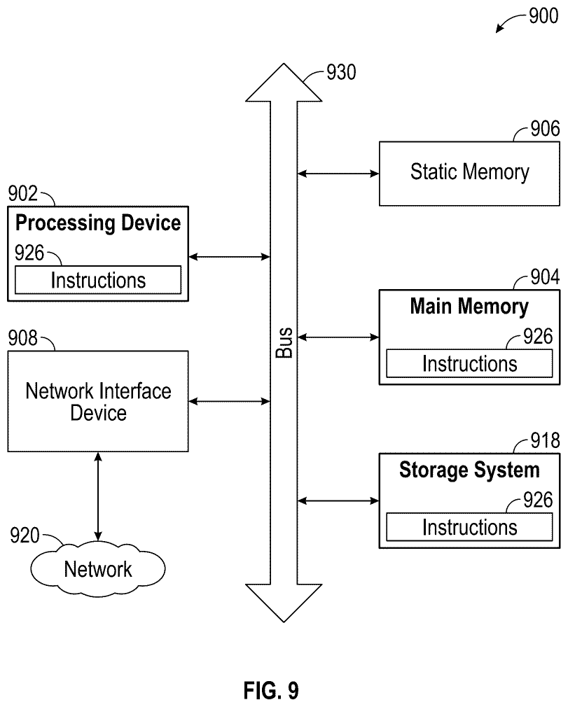

FIG. 9 illustrates a block diagram of an example machine (e.g., a host system) 900 which may include one or interconnect structures, vertical conductors, memory devices and/or memory systems as described above. As discussed above, machine 900 may benefit from enhanced memory performance from use of one or more of the described transistor structures and/or memory systems, facilitating improved performance of machine 900 (as for many such machines or systems, efficient reading and writing of memory can facilitate improved performance of a processor or other components that machine, as described further below.

In alternative embodiments, the machine 900 may operate as a standalone device or may be connected (e.g., networked) to other machines. In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 900 may include a processing device 902 (e.g., a hardware processor, a central processing unit (CPU), a graphics processing unit (GPU), a hardware processor core, or any combination thereof, etc.), a main memory 904 (e.g., read-only memory (ROM), dynamic random-access memory (DRAM) such as synchronous DRAM (SDRAM) or Rambus DRAM (RDRAM), etc.), a static memory 906 (e.g., static random-access memory (SRAM), etc.), and a storage system 918, some or all of which may communicate with each other via a communication interface (e.g., a bus) 930. In one example, the main memory 904 includes one or more memory devices as described in examples above.

The processing device 902 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 902 can also be one or more special-purpose processing devices such as an application specific integrated circuit (ASIC), a field programmable gate array (FPGA), a digital signal processor (DSP), network processor, or the like. The processing device 902 can be configured to execute instructions 926 for performing the operations and steps discussed herein. The computer system 900 can further include a network interface device 908 to communicate over a network 920.

The storage system 918 can include a machine-readable storage medium (also known as a computer-readable medium) on which is stored one or more sets of instructions 926 or software embodying any one or more of the methodologies or functions described herein. The instructions 926 can also reside, completely or at least partially, within the main memory 904 or within the processing device 902 during execution thereof by the computer system 900, the main memory 904 and the processing device 902 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 900 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 900 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 926 (e.g., software, programs, an operating system (OS), etc.) or other data are stored on the storage system 918 can be accessed by the main memory 904 for use by the processing device 902. The main memory 904 (e.g., DRAM) is typically fast, but volatile, and thus a different type of storage than the storage system 918 (e.g., an SSD), which is suitable for long-term storage, including while in an “off” condition. The instructions 926 or data in use by a user or the machine 900 are typically loaded in the main memory 904 for use by the processing device 902. When the main memory 904 is full, virtual space from the storage system 918 can be allocated to supplement the main memory 904; however, because the storage system 918 device is typically slower than the main memory 904, and write speeds are typically at least twice as slow as read speeds, use of virtual memory can greatly reduce user experience due to storage system latency (in contrast to the main memory 904, e.g., DRAM). Further, use of the storage system 918 for virtual memory can greatly reduce the usable lifespan of the storage system 918.

The instructions 926 may further be transmitted or received over a network 920 using a transmission medium via the network interface device 908 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 908 may include one or more physical jacks (e.g., Ethernet, coaxial, or phone jacks) or one or more antennas to connect to the network 920. In an example, the network interface device 908 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 900, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods.

The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1. A memory device, comprising; a stack of alternating dielectric layers and conductor layers; a number of liner interface material layers between the conductor layers and the dielectric layers; a number of memory cells formed within the stack of alternating dielectric layers and conductor layers; a vertical conductor passing between a top level of the stack and a bottom level of the stack; a lateral connection between a location along the vertical conductor and a selected conductor layer from the stack, wherein a direct interface is formed between the vertical conductor and the selected conductor layer; and a lateral isolation structure around the vertical conductor adjacent to at least one other conductor layer from the stack.

Example 2. The memory device of example 1, wherein the lateral isolation structure includes all other conductor layers below a level of the lateral connection in the stack.

Example 3. The memory device of example 1, wherein the liner interface material layer also extends between the lateral isolation structure and at least one other conductor layer from the stack.

Example 4. The memory device of example 1, wherein the liner interface material layers include dielectric constant higher than 20.

Example 5. The memory device of example 1, wherein the liner interface material layers include hafnium oxide.

Example 6. The memory device of example 1, wherein the lateral connection extends a distance away from a side of the vertical conductor.

Example 7. The memory device of example 6, wherein the vertical conductor and the lateral connection are integrally formed.

Example 8. The memory device of example 1, wherein the vertical conductor and the lateral connection include tungsten.

Example 9. The memory device of example 1, wherein the lateral connection is on a sidewall of the vertical conductor and the selected conductor layer and lateral connection are integrally formed.

Example 10. The memory device of example 1, wherein the lateral connection extends a distance away from a side of the vertical conductor and the lateral connection is thicker than the selected conductor layer.

Example 11. The memory device of example 1, wherein the lateral isolation structure includes silicon oxide.

Example 12. A memory device, comprising; a stack of alternating dielectric layers and conductor layers; a number of liner interface material layers between the conductor layers and the dielectric layers; a number of memory cells formed within the stack of alternating dielectric layers and conductor layers; a vertical conductor between a top level of the stack and a selected conductor layer from the stack; a lateral connection between the vertical conductor and a selected conductor layer from the stack, the lateral conductor forming a direct interface with the selected conductor layer; and a lateral isolation structure around the vertical conductor adjacent to at least one other conductor layer from the stack.

Example 13. The memory device of example 12, wherein the lateral isolation structure includes all other conductor layers below a level of the lateral connection in the stack.

Example 14. The memory device of example 12, wherein a portion of the liner interface material layer is located between the lateral isolation structure and at least one other conductor layer from the stack.

Example 15. The memory device of example 12, wherein the lateral connection extends a distance away from a side of the vertical conductor.

Example 16. The memory device of example 15, wherein the vertical conductor and the lateral connection are integrally formed.

Example 17. The memory device of example 16, wherein the vertical conductor and the lateral connection include tungsten.

Example 18. A method of forming a memory device, comprising; forming a staircase in a stack of alternating dielectric layers and placeholder layers; forming an etch selective layer on a tread of the staircase; filling the staircase with dielectric material to a top surface of the stack; forming a passage between the top surface of the stack and a bottom of the stack; replacing a portion of the placeholder layers to form one or more lateral isolation structures around the passage, below the etch selective layer; replacing a remaining portion of the placeholder layers with a liner material and a first conductor material to form lined conductor layers; removing the etch selective layer to form a lateral cavity and removing an exposed portion of the liner material; and filling the lateral cavity and the passage with a second conductor to form a direct interface with a selected conductor layer adjacent to the lateral cavity.

Example 19. The method of example 18, wherein forming the etch selective layer includes implanting carbon into the tread of the staircase.

Example 20. The method of example 18, wherein replacing a remaining portion of the placeholder layers with a liner material and a first conductor material includes replacing with a liner material having a dielectric constant higher than 20.

Example 21. The method of example 20, wherein replacing with a liner material having a dielectric constant higher than 20 includes replacing with hafnium oxide.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device, comprising;
a stack of alternating dielectric layers and conductor layers;
a number of liner interface material layers between the conductor layers and the dielectric layers;
a number of memory cells formed within the stack of alternating dielectric layers and conductor layers;
a vertical conductor passing between a top level of the stack and a bottom level of the stack;
a lateral connection between a location along the vertical conductor and a selected conductor layer from the stack, wherein a direct interface is formed between the vertical conductor and the selected conductor layer; and
a lateral isolation structure around the vertical conductor adjacent to at least one other conductor layer from the stack.

2. The memory device of claim 1, wherein the lateral isolation structure includes all other conductor layers below a level of the lateral connection in the stack.

3. The memory device of claim 1, wherein the liner interface material layer also extends between the lateral isolation structure and at least one other conductor layer from the stack.

4. The memory device of claim 1, wherein the liner interface material layers include dielectric constant higher than 20.

5. The memory device of claim 1, wherein the liner interface material layers include hafnium oxide.

6. The memory device of claim 1, wherein the lateral connection extends a distance away from a side of the vertical conductor.

7. The memory device of claim 6, wherein the vertical conductor and the lateral connection are integrally formed.

8. The memory device of claim 1, wherein the vertical conductor and the lateral connection include tungsten.

9. The memory device of claim 1, wherein the lateral connection is on a sidewall of the vertical conductor and the selected conductor layer and lateral connection are integrally formed.

10. The memory device of claim 1, wherein the lateral connection extends a distance away from a side of the vertical conductor and the lateral connection is thicker than the selected conductor layer.

11. The memory device of claim 1, wherein the lateral isolation structure includes silicon oxide.

12. A memory device, comprising;
a stack of alternating dielectric layers and conductor layers;
a number of liner interface material layers between the conductor layers and the dielectric layers;
a number of memory cells formed within the stack of alternating dielectric layers and conductor layers;
a vertical conductor between a top level of the stack and a selected conductor layer from the stack;
a lateral connection between the vertical conductor and a selected conductor layer from the stack, the lateral conductor forming a direct interface with the selected conductor layer; and
a lateral isolation structure around the vertical conductor adjacent to at least one other conductor layer from the stack.

13. The memory device of claim 12, wherein the lateral isolation structure includes all other conductor layers below a level of the lateral connection in the stack.

14. The memory device of claim 12, wherein a portion of the liner interface material layer is located between the lateral isolation structure and at least one other conductor layer from the stack.

15. The memory device of claim 12, wherein the lateral connection extends a distance away from a side of the vertical conductor.

16. The memory device of claim 15, wherein the vertical conductor and the lateral connection are integrally formed.

17. The memory device of claim 16, wherein the vertical conductor and the lateral connection include tungsten.

18. A method of forming a memory device, comprising;
forming a staircase in a stack of alternating dielectric layers and placeholder layers;
forming an etch selective layer on a tread of the staircase;
filling the staircase with dielectric material to a top surface of the stack;
forming a passage between the top surface of the stack and a bottom of the stack;
replacing a portion of the placeholder layers to form one or more lateral isolation structures around the passage, below the etch selective layer;
replacing a remaining portion of the placeholder layers with a liner material and a first conductor material to form lined conductor layers;
removing the etch selective layer to form a lateral cavity and removing an exposed portion of the liner material; and
filling the lateral cavity and the passage with a second conductor to form a direct interface with a selected conductor layer adjacent to the lateral cavity.

19. The method of claim 18, wherein forming the etch selective layer includes implanting carbon into the tread of the staircase.

20. The method of claim 18, wherein replacing a remaining portion of the placeholder layers with a liner material and a first conductor material includes replacing with a liner material having a dielectric constant higher than 20.

21. The method of claim 20, wherein replacing with a liner material having a dielectric constant higher than 20 includes replacing with hafnium oxide.
